(19) United States
(12) Patent Application Publication
(10) Pub. No.: US 2007/0194451 A1
(43) Pub. Date: Aug. 23, 2007

(54) Apparatus for integrated input/output circuit and verification method thereof

(76) Inventors: Chih-Hung Wu, Kaohsiung City (TW); Shwu-Fang Fu, Sinpu Township (TW)

Correspondence Address: J.C. Patents, Inc., Suite 250, 4 Venture, Irvine, CA, 92618, US

(21) Appl. No.: 11/360,712

(22) Filed: Feb. 22, 2006

(51) Int. Cl. H01L 23/52

(52) U.S. Cl. 257/758

(57) ABSTRACT

An apparatus for integrated input/output circuit and a verification method thereof are provided. The apparatus effectively reduces the chip area occupation and cost, and decreases the resistance on an electrical transmission path of the integrated input/output circuit to improve the circuit efficiency. The apparatus comprises a metal structure and a plurality of integrated circuit components. Wherein, the integrated circuit comprises the integrated circuit components and the metal structure that has a bonding pad. In addition, the integrated circuit components are disposed directly under the metal structure and coupled to the metal structure. In which, the metal structure provides an electrical transmission path for the integrated circuit.

### BACKGROUND OF THE INVENTION

1. Field of the Invention

The present invention relates to an integrated input/output circuit apparatus, and more particularly, to an integrated input/output circuit apparatus with a bonding pad and a verification method thereof.

2. Description of the Related Art

Along with the rapid growth of the integrated circuit (IC), the space occupation by the devices on the surface of the chip increases and the cost also corresponding increases. Wherein, each of the input/output (I/O) circuit, the electrostatic discharge (ESD) protection circuit, and the boding pad occupy a certain chip area, and in some cases such chip area is even larger than the space occupied by an active circuit. In general, the bonding pad is disposed on the periphery of the I/O circuit. If the boding pad, the I/O circuit and the active circuit are all directly formed on the same region, the chip area can be conserved and the cost can be significantly reduced. The technique for disposing the bonding pad on the active circuit region is referred to as a POC (pad on circuit) technique.

A typical wire bonding over active circuit (BOAC) is disclosed in U.S. Pat. No. 6,900,541. As shown in FIG. 1, the IC 110 comprises an active circuit region 12 and a boding pad region 10. Wherein, the bonding pad region 10 comprises a bonding pad 100. The active circuit 120 is disposed directly under the bonding pad 100, and the metal layers (M1, M2, and M3) work as its electrical transmission path. In addition, the metal layers (M4, M5, and M6) should be reserved for the bonding pad 100, therefore the resistance on the electrical transmission path of the IC circuit 100 and the ESD protection capability are further adversely impacted. However, if the metal layers (M4, M5, and M6) are needed, additional fabrication steps required, which would further increase the fabrication cost.

In the conventional semiconductor fabricating process, the metal layers of the I/O circuit apparatus are fixedly disposed. When it is intended to dispose the bonding pad in the same region as the I/O circuit apparatus, the I/O circuit apparatus has to reserve additional metal layers for the bonding pad, which sacrifices the metal layers outside the bonding pad. FIG. 2 schematically shows a sectional view illustrating a case where a bonding pad is integrated with an active circuit in the conventional fabricating process. The first circuit 200 is a sectional view of the I/O circuit, in which a plurality of neighboring metal layers (M3˜M6) are serially connected through a plurality of via plugs 205. As shown in FIG. 2, the bonding pad 210 is disposed on the second circuit 201. Since the metal layers (M5, M6) should be reserved for the bonding pad 210, the metal layers (M5, M6) do not exist outside the bonding pad 210. Accordingly, the number of metal layers that can be used by the circuit are reduced and the resistance on the electrical transmission path increases, which further adversely affects the ESD protection capability on the I/O circuit or even causes the electromigration problem. Moreover, the IR drop on the source line is increased when such I/O circuit is applied on it.

### SUMMARY OF THE INVENTION

Therefore, it is an object of the present invention to provide an apparatus for integrated input/output circuit. The apparatus effectively reduces the occupation of the chip area by disposing the bonding pad on the active circuit and the I/O circuit. In addition, when the bonding pad is integrated with the I/O circuit, a special circuit layout method is used to reduce the resistance on the electrical transmission path of the I/O circuit, such that the ESD protection capability is improved and the IR drop on the power line is reduced.

It is another object of the present invention to provide a method for verifying the integrated input/output circuit apparatus. In this verification method, the metal structure of the integrated I/O circuit apparatus is divided into a plurality of leaf cells. The location where the bonding pad should be disposed on is determined by the related testing process, such that the bonding pad can be directly formed in the metal structure without requiring additional steps in the fabricating process. With such verification method, the problems caused due to additional bonding pad into the I/O circuit, such as the deterioration of the ESD protection capability, the increase of resistance on the electrical transmission path, and the electromigration problem due to the different current density when a large current passes through a thinner part of the conductive wire, are effectively resolved.

In accordance with the above objects and other objects of the present invention, an apparatus for integrated input/output circuit is provided. The apparatus comprises a metal structure and a plurality of integrated circuit components. The metal structure and the integrated circuit components together form an integrated circuit, and the metal structure works as an electrical transmission path for the integrated circuit. In an embodiment, the metal structure mentioned above comprises a boding pad, and a bonding metal layer is disposed on the top layer of the bonding pad. The bonding metal layer is comprised of, for example, Al (aluminum), and a bonding window is included in the bonding metal layer as a bonding contact. Moreover, the metal structure mentioned above comprises a plurality of metal structures, and a plurality of via plugs is electrically coupled between two neighboring metal layers.

In an embodiment of the present invention, the integrated circuit comprises a metal structure and a plurality of integrated circuit components. Wherein, the integrated circuit components are directly disposed under the metal structure and coupled to the metal structure as an electrical transmission path. In an embodiment, the integrated circuit mentioned above further comprises an ESD protection circuit, and an I/O buffer circuit, etc. The integrated circuit components in the integrated circuit comprise an active device, a passive device, an ESD protection device, and an I/O device. Wherein, the active device may be an n-channel metal oxide semiconductor (NMOS) or a p-channel metal oxide semiconductor (PMOS). The passive device may be a capacitor, an inductor, a resistor, or a varactor.

In an embodiment, the integrated input/output circuit apparatus mentioned above includes a passivation layer, and the passivation layer covers a portion of the metal structure outside the region where the bonding window is disposed.

In accordance with the objects and other objects of the present invention, a method for verifying the integrated input/output circuit apparatus is provided. The verification method comprises the following steps. First, a plurality of leaf cells included in the metal structure is compared. Wherein, each leaf cell comprises at least a first leaf cell and a second leaf cell. The metal structure is formed in a layout hierarchy, wherein each leaf cell is one of the components constituting the metal structure, and each component represents a portion of the metal structure. Then, a corresponding layout location data is obtained according to the location where the bonding pad is disposed. Wherein, the corresponding layout data further comprises the leaf cell data of the bonding pad location corresponding to the metal structure.

Next, the integrated input/output circuit apparatus is tested by using the layout location data of different bonding pad locations, and a test result is obtained. Here, IR drop on the power line, electromigration and ESD protection capability of the integrated input/output circuit apparatus may be tested. Next, if the test data meet the requirements, the location for disposing the bonding pad is configured according to the test data, and the leaf cell on the corresponding location of the integrated input/output circuit apparatus is removed. If the test data does not meet the requirements, the location for disposing the bonding pad is modified, and a new corresponding layout location data is obtained and subsequently used to perform a new test. Finally, the bonding pad is coupled to the metal structure of the integrated input/output circuit apparatus according to the configured bonding pad location, and the bonding pad is disposed into the integrated input/output circuit apparatus.

In accordance with the preferred embodiment of the present invention, a special layout and fabricating technique to move the bonding pad to the I/O apparatus are applied to effectively decrease the occupation of the chip area and thereby reduce the manufacturing cost. In addition, a larger number of conductive metal layers are reserved to decrease the resistance on the electrical transmission path of the integrated input/output circuit apparatus. The lower resistance effectively improves the ESD protection capability on the I/O circuit, reduces the IR drop on the power line, and mitigates the electromigration problem.

### BRIEF DESCRIPTION DRAWINGS

The accompanying drawings are included to provide a further understanding of the invention, and are incorporated in and constitute a portion of this specification. The drawings illustrate embodiments of the invention, and together with the description, serve to explain the principles of the invention.

FIG. 1 schematically shows a circuit disclosed in U.S. Pat. No. 6,900,541.

FIG. 2 schematically shows a sectional view illustrating a case where a bonding pad is integrated with an active circuit in the conventional fabrication process.

FIG. 3 schematically shows a sectional view of an integrated input/output circuit apparatus according to an embodiment of the present invention.

FIG. 4 schematically shows a sectional view illustrating the relationship between the metal structure and the bonding pad according to an embodiment of the present invention.

FIG. 5 schematically shows a flow chart illustrating a method for verifying an integrated input/output circuit apparatus.

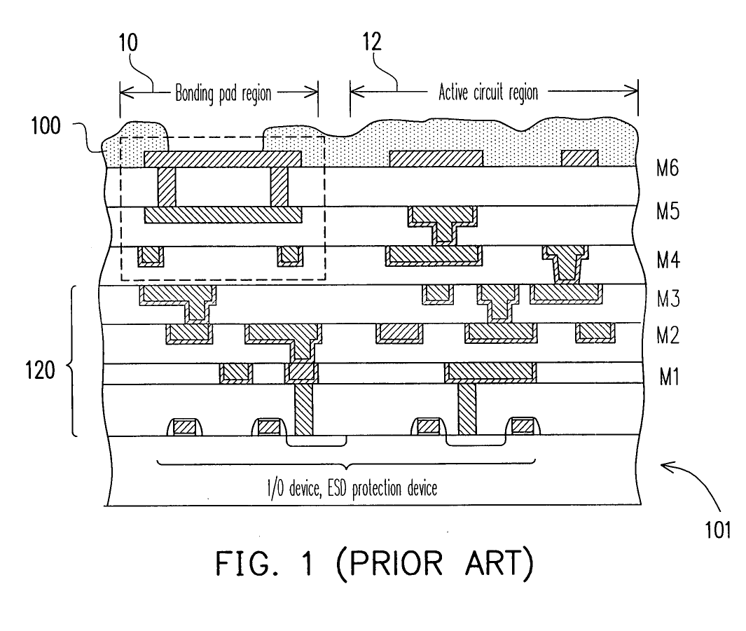

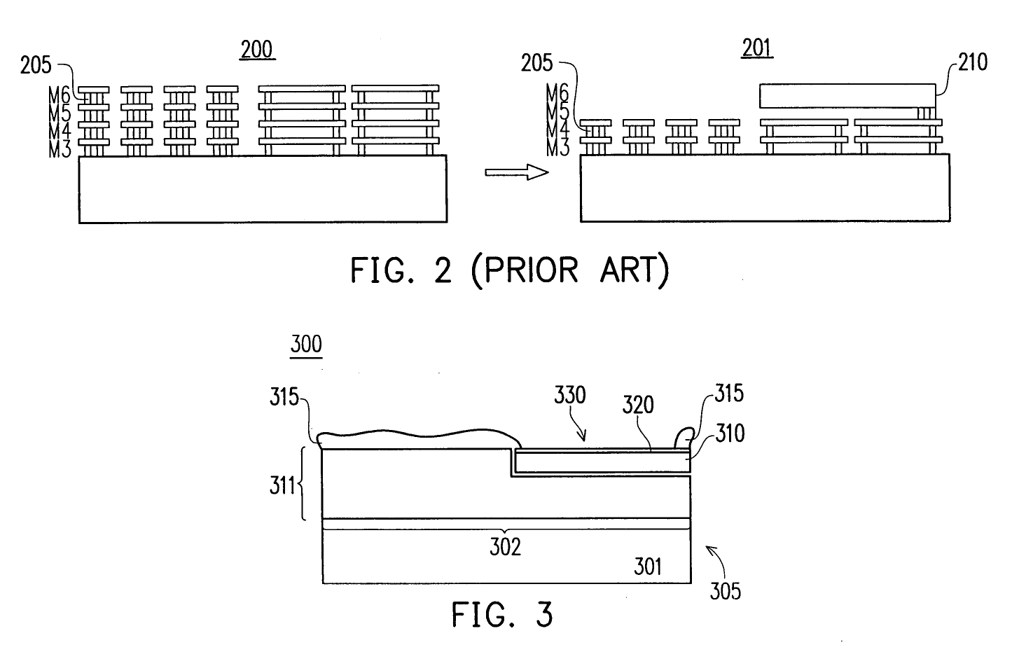

### DESCRIPTION PREFERRED EMBODIMENTS

FIG. 3 schematically shows a sectional view of an integrated input/output circuit apparatus according to an embodiment of the present invention. The integrated input/output circuit apparatus 300 comprises a metal structure 311 and an integrated circuit component 302. Wherein, the metal structure 311 comprises a bonding pad 310. The bonding pad 310 is comprised of a multi-layer structure, and the number of the metal layers is less than that of the metal structure 311. In addition, a bonding metal layer 320 disposed on the top layer of the bonding pad 310 has a bonding window 330. The bonding metal layer 320 is made of material suitable for the semiconductor fabrication process or made of metal material suitable for the bonding wire, such as Al, Cu, and Au. In addition to the boding window 330, a passivation layer 315 is deposited on the metal structure 311. The passivation layer 315 covers the metal structure 311 and may protect the metal structure 311 and thereby may eliminate the problems such as contamination, metal oxidation, or damage caused due to contact with the external components. Moreover, the bonding wire can be directly disposed on the bonding metal layer 320 through the bonding window 330.

The integrated circuit 305 comprises the metal structure 311 and the integrated circuit component 302. Wherein, the integrated circuit component 302 formed on the surface of a substrate 301 is directly disposed under the metal structure 311. The integrated circuit component 302 uses the metal structure 311 as its electrical transmission path to form the integrated circuit 305. In addition, the active device or the passive device and the special device may be deposited on the integrated circuit component 302 under the metal structure 311 according to the circuit design requirements. Wherein, the active or the passive device includes a PMOS transistor, a NMOS transistor, a resistor, an inductor and a capacitor. The special device includes the ESD protection device, an input/output cell, and an input/output buffer circuit.

The portion of the metal structure 311 outside the area occupied by the bonding pad 310 is comprised of a multi-layer metal structure. In addition, a plurality of via plugs 420 couples between two adjacent metal layers. Since the metal structure 311 is disposed outside the bonding pad 310, and the metal layers of the same layer used by the bonding pad 310 are reserved as the electrical transmission path. Thus, the resistance on the integrated input/output circuit apparatus 300 with such structure does not significantly increase even if the bonding pad 310 is disposed on the integrated input/output circuit apparatus 300. Accordingly, the ESD protection capability on the integrated input/output circuit apparatus 300 may not be adversely impacted, the IR drop on the power line may not be significantly increased, and the electromigration problem may be significantly reduced or eliminated.

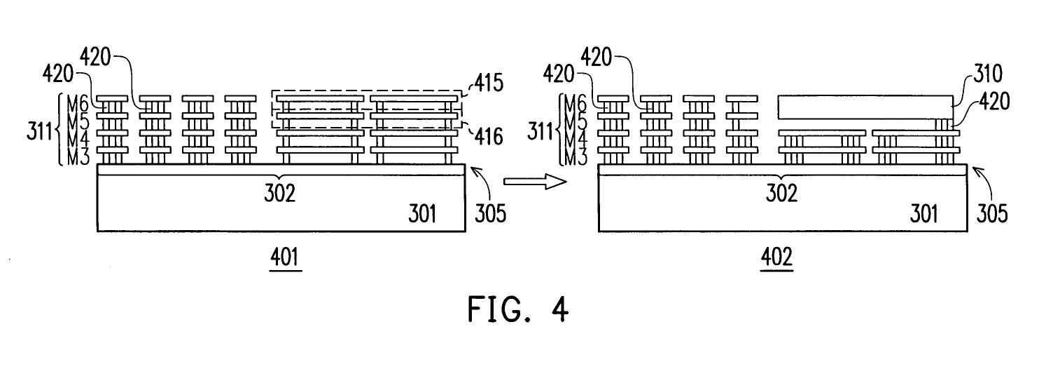

FIG. 4 schematically shows a sectional view illustrating the relationship between the metal structure and the bonding pad according to an embodiment of the present invention. As described in the embodiment of FIG. 3, the metal structure 311 is comprised of a multi-layer metal structure having, for example, four-layer metal structure, M3˜M6, and the bonding pad 310 is comprised of, for example, two metal layers M5 and M6. The material for fabricating the metal layers of the metal structure 311 and the bonding pad 310 are determined according to various semiconductor fabricating processes and circuit design requirements. However, the number of the metal layers and the location of the metal structure 311 are not necessarily limited in the present invention. The bonding pad 310 may be disposed on any location in the metal structure 311 based on the circuit design requirement as long as the top metal layer used by the bonding pad 310 is the same as that used by the metal structure 311.

In the present embodiment, the metal layer M6 is the top metal layer used by the bonding pad 310 and the metal structure 311 mentioned above. As shown in the sectional view, the metal structure 401 comprises the metal structure 311, a substrate 301 and an integrated circuit 305. The metal structure 311 is divided into a plurality of leaf cells with a layout hierarchy. Wherein, each leaf cell represents a portion of the metal structure 311. Specifically, the first leaf 415 comprises a portion of the metal layer M6 and a plurality of via plugs 420 between the metal layer M6 and the metal layer M5 in this area. The second leaf 416 comprises a portion of the metal layer M5 and a plurality of via plugs 420 between the metal layer M5 and the metal layer M4 in this area, and so on. Other area of the metal structure 311 may be comprised of various leaf cells, and its detail is omitted herein.

The integrated circuit 305 is composed of the integrated circuit component 302 disposed on the surface of the substrate 301 and the metal structure 311. When it is desired to add the bonding pad 310 into the metal structure 311 of the integrated circuit 305, the sectional view of the metal structure structure is as shown in the sectional view 402. In the present embodiment, the metal layers M5 and M6 are the metal layers used by the bonding pad 310. Referring to the location of the bonding pad 310 in the metal structure 311, the corresponding leaf cells are the first leaf cell 415 and the second leaf cell 416, and the first and second leaf cells 415 and 416 are replaced by the bonding pad 310. The bonding pad 310 is electrically coupled to the metal structure 311 through the corresponding via plugs 420 or by using a metal wire layout routing method. In addition, the bonding pad 310 is not necessarily limited to be disposed on the specific location of the metal structure 310. Moreover, the bonding pad 310 replaces the corresponding leaf cells according to the different locations on the metal structure 311.

The metal structure containing the bonding pad is as shown in the sectional view 402. The bonding pad 310 is directly disposed in the integrated circuit 305, and the external device can electrically couple to the integrated circuit 305 through the bonding pad 310 by a bonding wire connection. With the circuit structure of the present invention, therefore additional chip area is not required for the bonding pad 310, which would significantly reduce the space occupation of the chip and thereby reduce the cost.

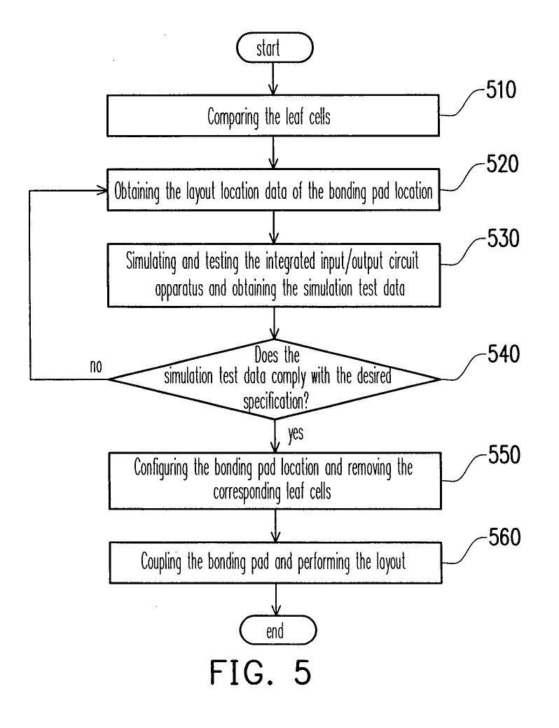

The present invention further provides a method for verifying the integrated input/output circuit apparatus. The verification method defines the appropriate location for disposing the bonding pad 310 and designs the circuit layout by using different electrical tests and simulations. For better understanding by the ordinary skills in the art, the technique of the present invention is described in great detail with reference to the system shown in FIG. 4 hereinafter. FIG. 5 schematically shows a flow chart illustrating a method for verifying an integrated input/output circuit apparatus.

First, at step 510, the leaf cells in the metal structure 311 are compared, and the layout location data corresponding to the metal structure 311 is obtained according to the layout it represents. According to the hierarchical layout structure, the metal structure 311 is composed of a plurality of leaf cells, which includes the first leaf cell 415 and the second leaf cell 416. Of course, the leaf cells need not necessarily be limited to only two cells. Any component constituting a part of the metal structure 311 may also be regarded as a leaf cell. Here, each leaf cell represents a layout pattern on different location of the metal structure 3 11. Next, in step 520, the layout location data of the bonding pad 310 is obtained. Moreover, the location of the bonding pad 310 in the metal structure 311 is configured according to its location, and the corresponding layout location data is obtained. In the present embodiment, the layout location data includes the location data of the first leaf cell 415 and the second leaf cell 416.

Next, in step 530, the integrated input/output circuit apparatus is tested and a test data is obtained. Wherein, the integrated input/output circuit apparatus is tested by using the layout location data of different bonding pad locations. The test items include testing the IR drop on the power line when the integrated input/output circuit apparatus is applied, testing the electromigration problem caused by different current densities, and testing the ESD protection capability. Then, the related test results are processed at step 540. Wherein, step 540 analyzes the test results provided by the step 530, whether or not all test data compile with the desired specification of the designer, the process proceeds to step 550. At step 550, the location of the bonding pad 310 is configured according to the related test data, and the corresponding leaf cell is removed according to the layout location data obtained at step 520. In the present embodiment, the corresponding leaf cells are the first leaf cell 415 and the second leaf cell 416. If the test data do not compile with the desired specification of the designer, the location of the bonding pad 310 is modified and the process returns to step 520 where the layout location data of the bonding pad 310 is obtained again and the test process is repeated until the test result compiles with the specification. Finally, after the location of the bonding pad 310 is affirmed, the process goes to step 560 where the bonding pad 310 is coupled and the layout is performed. The bonding pad 310 is coupled to the metal structure 311 of the integrated input/output circuit apparatus by using via plugs 420 with the metal wire routing method according to the configured bonding pad location. Finally, the layout and verification of the integrated input/output circuit apparatus are completed.

In summary, with the structure of the present invention, the bonding pad is disposed on the active circuit and the input/output circuit, which effectively reduces the chip area occupation and reduces cost. In addition, the metal structure of the integrated input/output circuit apparatus is divided into a plurality of leafs by using a special layout, which increases the number of metal layers that can be used by the metal structure and thereby reduce the resistance on the electrical transmission path of the input/output circuit, and improve the circuit efficiency. Moreover, the bonding pad is directly formed in the metal structure according to the bonding pad location determined in the related testing process without needing to add additional steps in the fabricating process. By using the verification method of the present invention, the problems such as the ESD protection capability deterioration and increase in the resistance of the electrical transmission path of the integrated input/output circuit apparatus caused due to additional bonding pad, are effectively reduced. In addition, the electromigration problem caused by the different current density is minimized, which prevents the metal conductive layer from being damaged by the electrostatic current.

Although the invention has been described with reference to a particular embodiment thereof, it will be apparent to one of the ordinary skills in the art that modifications to the described embodiment may be made without departing from the spirit of the invention. Accordingly, the scope of the invention will be defined by the attached claims not by the above detailed description.

What is claimed is:

1. An integrated input/output circuit apparatus, comprising:
a metal structure, comprising a bonding pad, wherein the bonding pad comprises a bonding metal layer disposed on a top surface of the bonding pad for providing a bonding window;
an integrated circuit component, formed on a substrate, wherein the integrated circuit component is disposed under the metal structure and coupled to the metal structure;
wherein, the metal structure and the integrated circuit component together form an integrated circuit, and the metal structure provides an electrical transmission path for the integrated circuit.

2. The integrated input/output circuit apparatus of claim 1, wherein the metal structure comprises a multi-layer metal structure.

3. The integrated input/output circuit apparatus of claim 2, wherein the metal structure comprises a plurality of via plugs coupled between two adjacent metal layers.

4. The integrated input/output circuit apparatus of claim 1, wherein a passivation layer is disposed on the metal structure, and the bonding window is not covered by the passivation layer.

5. The integrated input/output circuit apparatus of claim 1, wherein the bonding metal layer comprises Al (aluminum).

6. The integrated input/output circuit apparatus of claim 1, wherein the integrated circuit comprises an input/output buffer circuit.

7. The integrated input/output circuit apparatus of claim 1, wherein the integrated circuit comprises an electrostatic discharge (ESD) protection circuit.

8. The integrated input/output circuit apparatus of claim 1, wherein the integrated circuit comprises a plurality of transistors.

9. The integrated input/output circuit apparatus of claim 1, wherein the integrated circuit component comprises an input/output device.

10. The integrated input/output circuit apparatus of claim 1, wherein the integrated circuit component comprises an electrostatic discharge (ESD) protection circuit.

11. A method for verifying an integrated input/output circuit apparatus, comprising:
comparing a plurality of leaf cells in a metal structure;
obtaining a corresponding layout location data according to a bonding pad location;
testing the integrated input/output circuit apparatus and obtaining a test data including layout location data of different bonding pad locations;
configuring the bonding pad location according to the test data; and
coupling the bonding pad to the metal structure of the integrated input/output circuit apparatus according to the configured location of the bonding pad.

12. The method for verifying the integrated input/output circuit apparatus of claim 11, wherein when comparing the plurality of leaf cells in the metal structure, the leaf cell comprises a first leaf cell.

13. The method for verifying the integrated input/output circuit apparatus of claim 11, wherein when comparing the plurality of leaf cells in the metal structure, the leaf cell comprises a second leaf cell.

14. The method for verifying the integrated input/output circuit apparatus of claim 11, wherein when obtaining the corresponding layout location data according to the bonding pad location, the layout location data comprises a leaf cell data in the bonding pad.

15. The method for verifying the integrated input/output circuit apparatus of claim 11, wherein when obtaining the corresponding layout location data according to the bonding pad location, the step further comprises modifying the bonding pad location and obtaining a corresponding layout location data.

16. The method for verifying the integrated input/output circuit apparatus of claim 11, wherein when testing the integrated input/output circuit apparatus and obtaining the test data with the layout location data of different bonding pad locations, the test data further comprise a test result of the IR drop on the integrated input/output circuit apparatus, a test result of electromigration, and a test result of ESD protection capability.

17. The method for verifying the integrated input/output circuit apparatus of claim 11, wherein when configuring the bonding pad location according to the test data, the step further comprises:
obtaining the test data of the layout location data;
wherein if the test data complies with the desired specification, leaf cells of the corresponding locations are removed; and
if the test data does not comply with the desired specification, the bonding pad location is modifies and the step of obtaining the corresponding layout location data according to the bonding pad location is repeated.
